(19) United States
(12) Patent Application Publication
(10) Pub. No.: US 2025/0098127 A1
(43) Pub. Date: Mar. 20, 2025

(54) ELECTRONIC DEVICE

(71) Applicant: HYUNDAI MOBIS CO., LTD., Seoul (KR)

(72) Inventors: Chan Woong JUNG, Yongin-si (KR); Jang Hoon LEE, Yongin-si (KR); Won Ju KIM, Yongin-si (KR); Sang Il LEE, Yongin-si (KR); Kang Il MA, Yongin-si (KR); Hae Jung KIM, Yongin-si (KR); Ji Min SONG, Yongin-si (KR)

(73) Assignee: HYUNDAI MOBIS CO., LTD., Seoul (KR)

(21) Appl. No.: 18/400,880

(22) Filed: Dec. 29, 2023

(30) Foreign Application Priority Data
Sep. 20, 2023 (KR) 10-2023-0125697

(51) Int. Cl. H05K 7/20

(52) U.S. Cl. CPC H05K 7/20854; H05K 7/20881

(57) ABSTRACT

An electronic device includes a housing, a slot disposed in an interior of the housing, wherein the slot is configured to permit an electronic module inserted into the slot, a cooling member disposed outside the slot to cool the electronic module, and a heat transfer member configured to be connected to the electronic module to transfer heat from the electronic module to the cooling member.

### CROSS-REFERENCE TO RELATED APPLICATIONS

This application claims priority from and the benefit of Korean Patent Application No. 10-2023-0125697, filed on Sep. 20, 2023, which is hereby incorporated by reference for all purposes as if set forth herein.

### TECHNICAL FIELD

Exemplary embodiments of the present disclosure relate to an electronic device, and more particularly, to an electronic device installed in a vehicle.

### BACKGROUND

The vehicle cockpit is equipped with many different types of electronic parts performing electronic functions of a vehicle, wherein these electronic parts are mounted in a limited space. This creates many space constraints in designing for mounting.

In addition, respective electronic parts generate a lot of heat from high-performance circuit components due to its advanced functionality. As a result, heat sinks, heat dissipation fans, or the like is used to secure the high-temperature operation performance of a product, but this increases weight, causes noise problems, and increases the cost due to additional heat dissipation components.

In addition, respective electronic parts are distributed in various places in the cockpit so as to be connected to respective component's connectors through a main cable. This leads to increased cable length, excessive material costs, and weight.

The background technology of the present disclosure is disclosed in Unexamined Korean Patent Publication No. 10-2013-0001647 (published on Jan. 4, 2013 and entitled ‘Display Device’).

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Various embodiments are directed to an electronic device with electronic parts, performing various functions associated with vehicle operations, integrated into a single module.

In an embodiment, an electronic device includes: a housing; a slot disposed in an interior of the housing; an electronic module inserted into the slot; a cooling member disposed outside the slot to cool the electronic module; and a heat transfer member connected to the electronic module to transfer heat from the electronic module to the cooling member.

The plurality of slots may be provided so that the plurality of slots adjoin each other in the interior of the housing.

The slot may include a first end and a second end spaced apart from each other, and the cooling member may include a heat sink, disposed facing the first end of the slot, in contact with the electronic module, and through which a coolant is introduced or discharged, a circulation line connected to the heat sink and through which the coolant is circulated, and a chiller connected to the circulation line to cool the coolant flowing through the circulation line.

The electronic module may include a first side disposed facing the first end; and a second side disposed intersecting the first side, wherein the heat transfer member may include a heat pipe disposed on the second side.

A cross-sectional area of the electronic module may be smaller than a cross-sectional area of the slot, and the heat pipe may be spaced apart from the housing.

The electronic device may further include a fastening member movably mounted on the electronic module to selectively fasten the electronic module to the housing depending on a movement direction.

The cross-sectional area of the electronic module may be smaller than the cross-sectional area of the slot, and the fastening member may include: a base member reciprocally movably mounted along a first direction parallel to an insertion direction of the electronic module into the slot; and a switching member disposed between the base member and the electronic module to switch the movement direction of the base member from the first direction to a second direction intersecting the first direction, the base member being in contact with the housing as the base member moves in the second direction.

The switching member may include a first wedge having a first inclined surface protruding from the electronic module and disposed inclined to the first direction; and a second wedge having a second inclined surface protruding from the base member and being in contact with the first inclined surface.

The first wedge may have a trapezoidal cross-sectional shape.

The first wedge and the second wedge may be provided in plural, and the plurality of the first wedge and the plurality of the second wedge may be arranged alternately along the longitudinal direction of the base member.

The length of the first inclined surface and the length of the second inclined surface along the second direction may be greater than a travel distance of the base member in the second direction.

The electronic device may further include an adjustment member connected to the electronic module to regulate the movement of the base member.

The adjustment member may include: an adjustment body rotatably connected to the electronic module; a cam disposed on one side of the adjustment body to press or release the base member in the first direction depending on a rotation direction of the adjustment body; and a lever extending from the other side of the adjustment body.

The cam may protrude from an outer surface of the adjustment body in a radial direction of the adjustment body.

A protrusion length of the cam may be greater than a gap between the adjustment body and the base member.

In the electronic device according to the present disclosure, the electronic modules performing different functions may be housed inside a single housing, thereby increasing the utilization of space inside the cockpit and facilitating the replacement and maintenance of electronic modules.

In the electronic device according to the present disclosure, the plurality of electronic modules may be cooled simultaneously through a single heat sink and the circulation line may be connected to a battery cooling system pre-installed in a vehicle, thereby preventing an excessive increase in the size of the cooling system and reducing the building cost of the cooling system.

In the electronic device according to the present disclosure, the cooling efficiency of the electronic module may be further improved by directing the heat from the electronic module toward the cooling member with the heat transfer member.

In the electronic device according to the present disclosure, the attachment/detachment of the electronic module to/from the slot may be facilitated by the fastening member and the adjustment member.

In the electronic device according to the present disclosure, the cooling rate of the electronic device may be further improved by distributing, to the base member, the first wedge, and the second wedge, remaining in constant contact, part of the heat transferred to the heat transfer member.

### BRIEF DESCRIPTION OF THE DRAWINGS

FIG. 1 is an exploded perspective view schematically illustrating the configuration of an electronic device according to an embodiment of the present disclosure.

FIG. 2 is a cross-sectional view schematically illustrating the configuration of the electronic device according to the embodiment of the present disclosure.

FIG. 3 is a perspective view schematically illustrating the configuration of a housing according to an embodiment of the present disclosure.

FIG. 4 is a front view schematically illustrating the configuration of the housing according to the embodiment of the present disclosure.

FIG. 5 is a cross-sectional view schematically illustrating the configuration of the housing according to the embodiment of the present disclosure.

FIGS. 6 and 7 are views illustrating variations of a slot illustrated in FIG. 4.

FIG. 8 is a perspective view schematically illustrating the configuration of an electronic module according to an embodiment of the present disclosure.

FIG. 9 is a cross-sectional perspective view schematically illustrating the configuration of the electronic module according to the embodiment of the present disclosure.

FIG. 10 is an exploded perspective view schematically illustrating the configuration of the electronic module according to the embodiment of the present disclosure.

FIG. 11 is a view schematically illustrating the configuration of a cooling element according to an embodiment of the present disclosure.

FIG. 12 is a diagram illustrating a heat dissipation process by a cooling member and a heat transfer member according to an embodiment of the present disclosure.

FIG. 13 is a perspective view schematically illustrating the configuration of a fastening member according to an embodiment of the present disclosure.

FIG. 14 is a cross-sectional view schematically illustrating the configuration of the fastening member according to the embodiment of the present disclosure.

FIG. 15 is an enlarged view schematically illustrating the configuration of a switching member according to an embodiment of the present disclosure.

FIG. 16 is a view schematically illustrating the configuration of an adjustment member according to an embodiment of the present disclosure.

FIGS. 17 through 19 are views schematically illustrating an operation process of the fastening member and the adjustment member according to an embodiment of the present disclosure.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Advantages and features of the present disclosure and methods of achieving the advantages and features will be clear with reference to embodiments described in detail below together with the accompanying drawings. However, the present disclosure is not limited to the embodiments disclosed herein but will be implemented in various forms. The embodiments of the present disclosure are provided so that the present disclosure is completely disclosed, and a person with ordinary skill in the art can fully understand the scope of the present disclosure. The present disclosure will be defined only by the scope of the appended claims. Meanwhile, the terms used in the present specification are for explaining the embodiments, not for limiting the present disclosure.

Terms, such as first, second, A, B, (a), (b) or the like, may be used herein to describe components. Each of these terminologies is not used to define an essence, order or sequence of a corresponding component but used merely to distinguish the corresponding component from other component(s). For example, a first component may be referred to as a second component, and similarly the second component may also be referred to as the first component.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween.

The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Hereinafter, embodiments of an electronic device according to the present disclosure will be described with reference to the accompanying drawings.

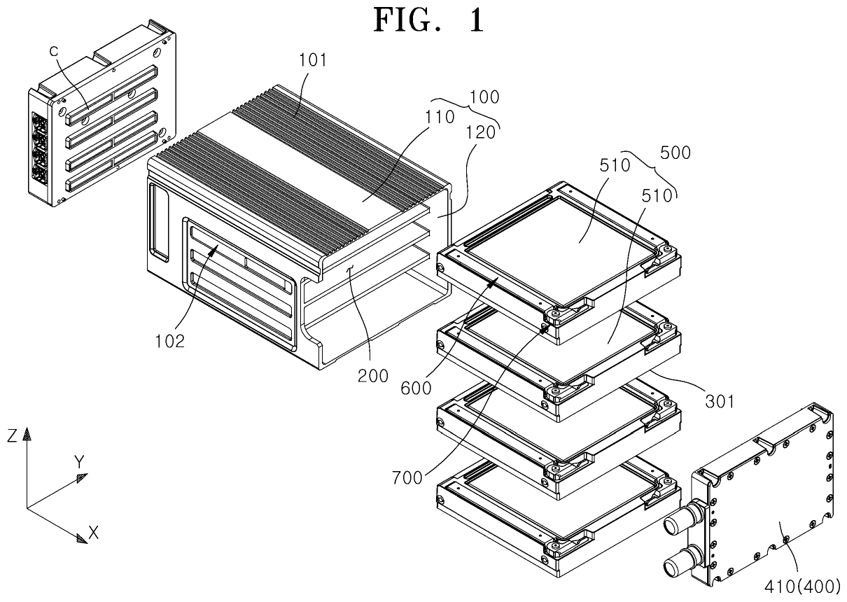

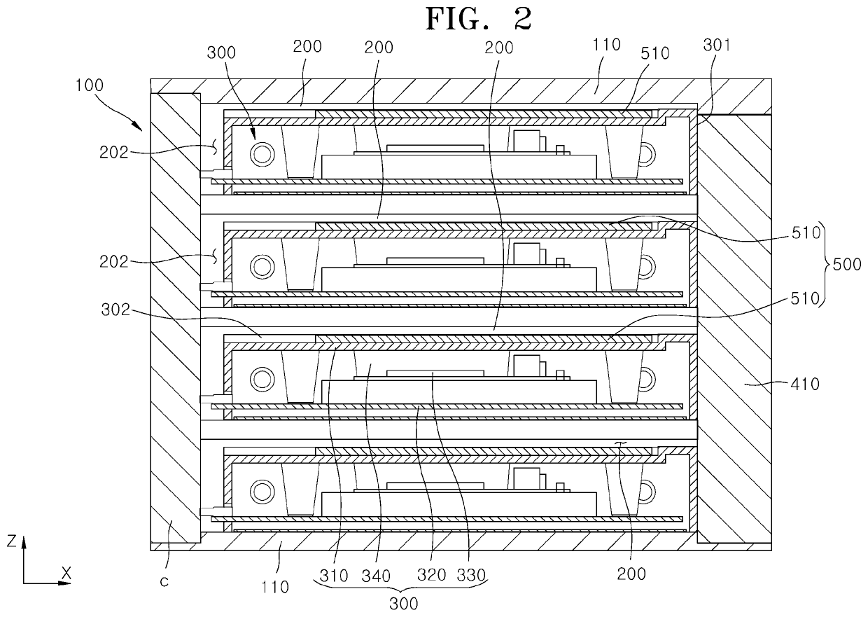

FIG. 1 is an exploded perspective view schematically illustrating the configuration of an electronic device according to an embodiment of the present disclosure, and FIG. 2 is a cross-sectional view schematically illustrating the configuration of the electronic device according to the embodiment of the present disclosure.

Referring to FIGS. 1 and 2, the electronic device according to the embodiment includes a housing 100, a slot 200, an electronic module 300, a cooling member 400, and a heat transfer member 500.

The housing 100 forms the schematic appearance of the electronic device and may support the electronic module 300, which is described later. The housing 100 may be formed to have a roughly cuboidal box shape. The housing 100 may be formed of a metal material, such as aluminum, steel, or the like, that has sufficient rigidity and high thermal conductivity. The housing 100 may be mounted inside a cockpit of a vehicle. The housing 100 may be secured inside the cockpit by various fastening means, such as brackets (not shown).

As described herein, a longitudinal direction of the housing 100 may refer to a direction parallel to an X-axis with respect to FIG. 1, a width direction of the housing 100 may refer to a direction parallel to a Y-axis with respect to FIG. 1, and a height direction or up-down direction of the housing 100 may refer to a direction parallel to a Z-axis with respect to FIG. 1.

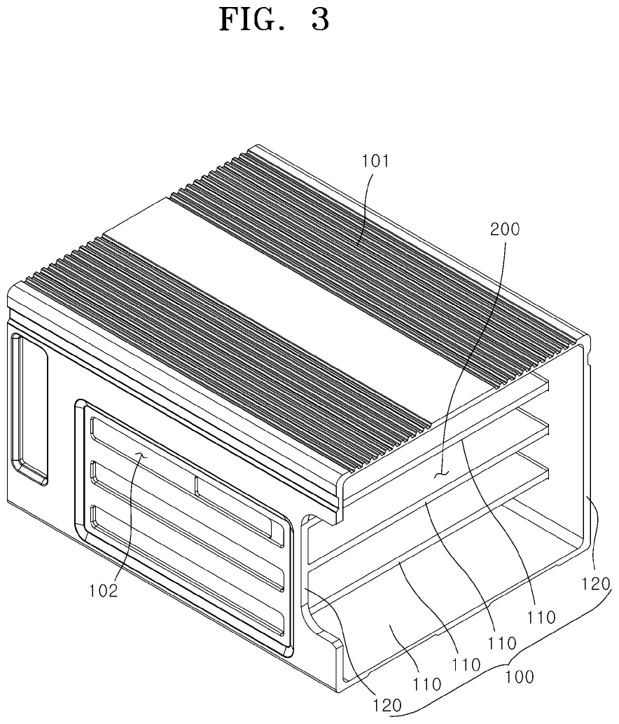

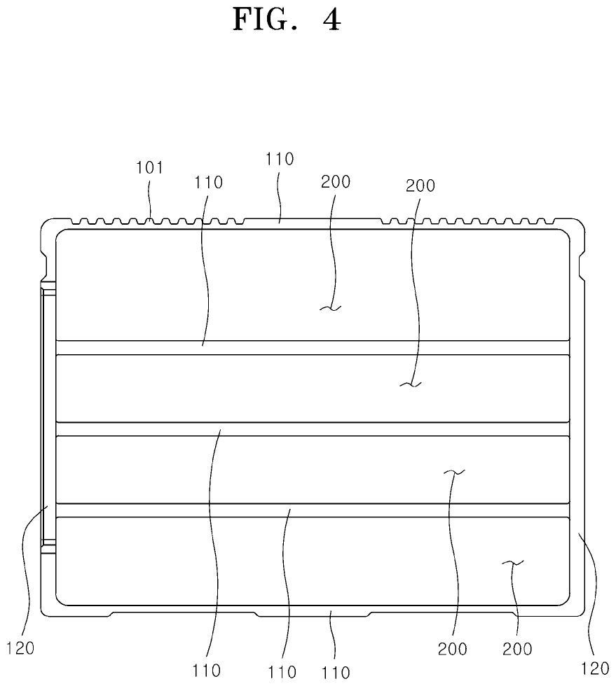

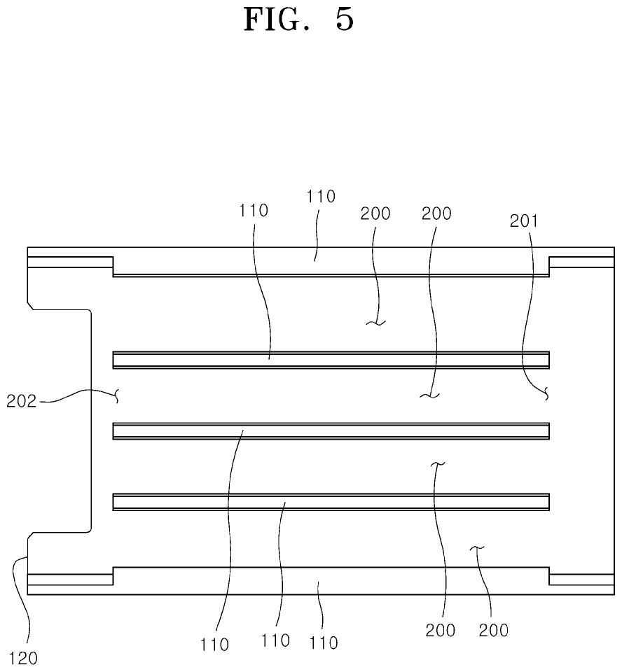

FIG. 3 is a perspective view schematically illustrating the configuration of a housing according to an embodiment of the present disclosure, FIG. 4 is a front view schematically illustrating the configuration of the housing according to the embodiment of the present disclosure, and FIG. 5 is a cross-sectional view schematically illustrating the configuration of the housing according to the embodiment of the present disclosure.

Referring to FIGS. 1 through 5, the housing 100 may include a first plate 110 and a second plate 120.

The first plate 110 may be disposed parallel to the ground (X-Y plane with respect to FIG. 1). The plurality of first plates 110 may be stacked along a vertical direction. A pair of first plates 110 adjacent along the vertical direction may be spaced apart by a predetermined distance. The gaps between pairs of first plates 110 may be formed identical to each other, or may be formed different from each other. While FIG. 1 illustrates five first plates 110, the number of first plates 110 is not limited to 5, and the design may be varied within a range of two or more.

The second plate 120 may be disposed intersecting the first plate 110. In an example, the second plate 120 may be disposed perpendicular to the ground and the first plate 110. A plurality of second plates 120 may be provided so that the plurality of second plates 120 are arranged along a width direction of the housing 100. In an example, the second plates 120 may be formed in a pair such that respective inner surfaces face opposite ends of the respective first plates 110, each spaced apart in the width direction of the housing 100. The pair of second plates 120 may be secured at their inner surfaces to the opposite ends of the first plates 110, respectively.

While the above description illustrates two second plates 120, the number of second plates 120 is not limited to 2, and may be three or more. In this case, the gap between pairs of second plates 120 may be identical to each other, or may be different from each other.

The housing 100 may be provided with heat sink fins 101 and heat sink holes 102 for dissipating heat generated by the electronic module 300 described below to the outside of the housing 100.

The heat sink fin 101 may protrude from the housing 100 to expand the contact area between the housing 100 and external air. The heat sink fin 101 may be formed to have the shape of a fin protruding upwardly from a top surface of the uppermost first plate 110 of the plurality of first plates 110. The plurality of heat sink fins 101 may be provided. The plurality of heat sink fins 101 may be spaced apart from each other on the first plate 110.

The heat sink hole 102 may be formed through the housing 100 to provide a path for air in the housing 100 to be exhausted to an external space outside the housing 100. The heat sink hole 102 may be formed to have the form of a hole perpendicularly penetrating an outer surface and an inner surface of the second plate 120. A plurality of heat sink holes 102 may be provided. The plurality of heat sink holes 102 may be spaced apart from each other on the second plate 120. The plurality of heat sink holes 102 may be formed separately in respective second plates 120, or may be formed in only the outermost second plate 120 of the plurality of secondary plates 120.

The slots 200 may be disposed in the interior of the housing 100, and may function as a configuration to provide a space in the interior of the housing 100 in which the electronic module 300 described below may be housed. In this embodiment, the slot 200 may be illustrated as an empty space surrounded by a pair of neighboring first plates 110 and a pair of neighboring second plates 120.

The slot 200 may include a first end 201 and a second end 202 spaced apart from each other along a longitudinal direction of the housing 100. The first end 201 and the second end 202 may be formed to be open.

A plurality of slots 200 may be provided. The plurality of slots 200 may adjoin each other in the interior of the housing 100 by the first plates 110 and the second plates 120. In an example, as illustrated in FIG. 4, the four slots 200 may be provided and stacked in a row along a vertical direction. The cross-sectional areas of the plurality of slots 200 may be identical to each other, or may be formed different from each other. The number of plurality of slots 200 is not limited to that illustrated in FIG. 4, but may be varied in design depending on the number of first plates 110 and second plates 120.

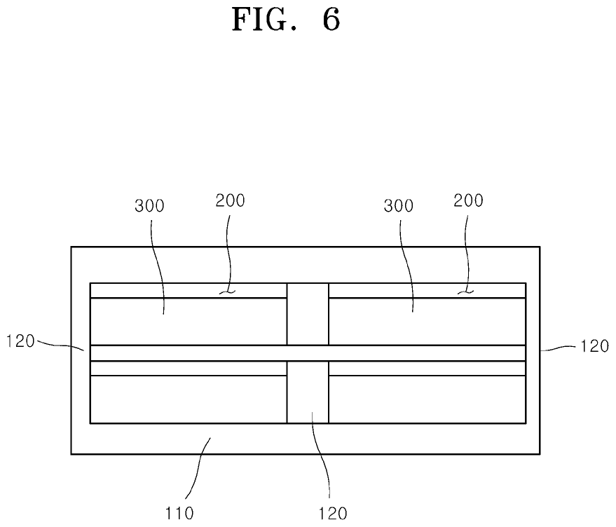

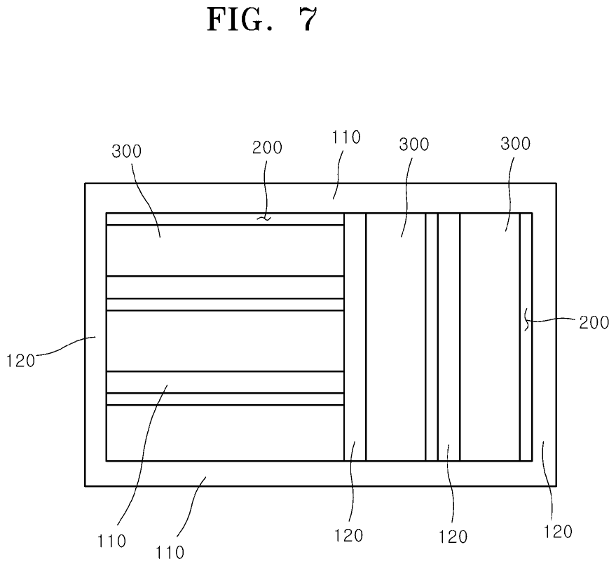

FIGS. 6 and 7 are views illustrating variations of a slot illustrated in FIG. 4.

Referring to FIG. 6, the plurality of slots 200 may be arranged in two or more rows along the width direction and the vertical direction of the housing 100. In an example, four slots 200 may be formed such that the four slots are disposed in two rows along the width direction and the vertical direction of the housing 100, respectively. The number of slots 200 and the number of rows of the slots 200 are not limited to those illustrated in FIG. 6, but may be varied in design depending on the number of first plates 110 and second plates 120.

Referring to FIG. 7, any one pair of slots 200 of the plurality of slots 200 may be disposed intersecting each other in the interior of the housing 100. In an example, some of the slots 200 may be disposed parallel to the first plate 110 in the width direction, while the other slots 200 may be disposed parallel to the second plate 120 in the width direction. In this case, the plurality of first plates 110 may be formed to have different lengths along the width direction of the housing 100, and the gap between neighboring second plates 120 may be different from each other. Conversely, the plurality of second plates 120 may be formed to have different lengths along the vertical direction, and the gap between neighboring first plates 110 may be different from each other.

The electronic module 300 may be inserted into the interior of the slot 200. Examples of the electronic module 300 may include a computer, a terminal, or an electronic control unit capable of performing various vehicle electronic functions, such as Advanced Driver Assistance Systems (ADAS), Audio Video Navigation (AVN), autonomous driving, amplifier, communication, artificial intelligence modules, and the like.

The electronic module 300 may be inserted into the interior of the slot 200 via the first end 201 or the second end 202. The electronic module 300 may be slidably moved in a direction parallel to the longitudinal direction of the housing 100 and may be inserted into the interior of the slot 200 or removed from the interior of the slot 200.

The electronic module 300 may include a first side 301 and a second side 302 intersecting each other.

In the following, an example in which when the electronic module 300 is inserted into the interior of the slot 200, the first side 301 and the second side 302 indicate a side of the overall perimeter of the electronic module 300 disposed to face the first end 201 and a top surface of the electronic module 300, respectively, will be described. However, the first side 301 and the second side 302 are not limited to the above configuration, and the first side 301 may be a side of the overall perimeter of the electronic module 300 disposed to face the second end 202, and the second side 302 may be a lateral side of the electronic module 300.

An undersurface of the electronic module 300 may be in contact with a top surface of the first plate 110 facing the lower side of the slot 200. The cross-sectional area of the electronic module 300 may be smaller than the cross-sectional area of the slot 200. In this case, the second side 302 may be disposed a predetermined distance apart from an undersurface of the first plate 110 facing the top side of the slot 200.

A plurality of electronic modules 300 may be provided. The plurality of electronic modules 300 may be respectively inserted into the interiors of the slots 200. Each electronic module 300 may individually perform one or more of the following functions: advanced driver assistance systems (ADAS), audio video navigation (AVN), autonomous driving, amplifier, communication, and artificial intelligence modules. The size and shape of the electronic modules 300 may be the same, or alternatively, they may be different from each other.

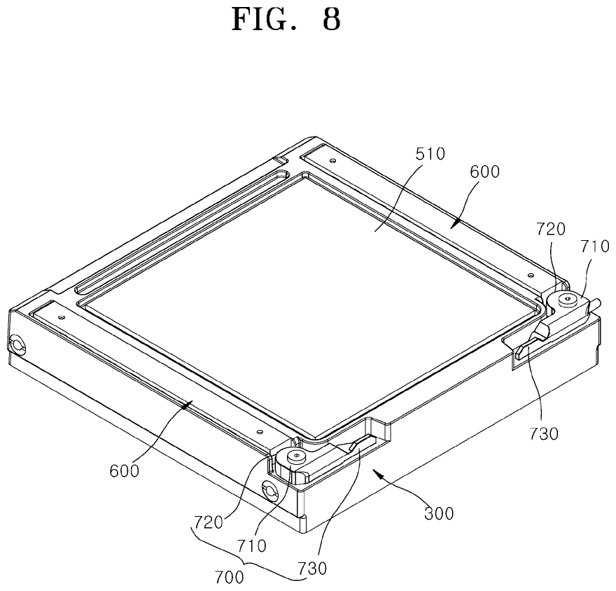

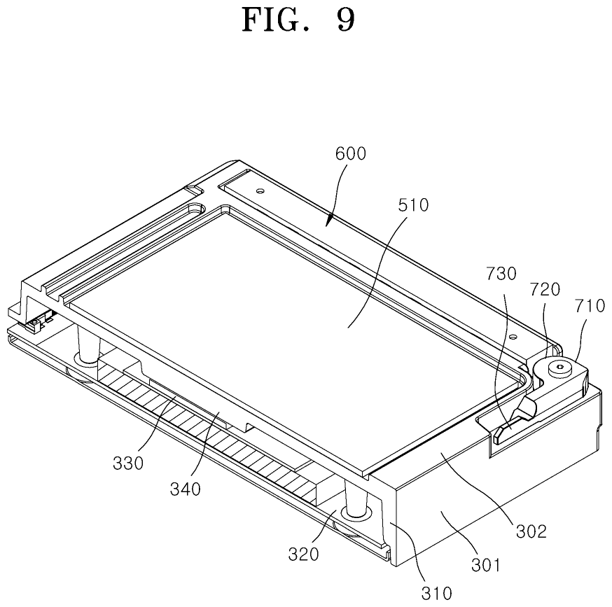

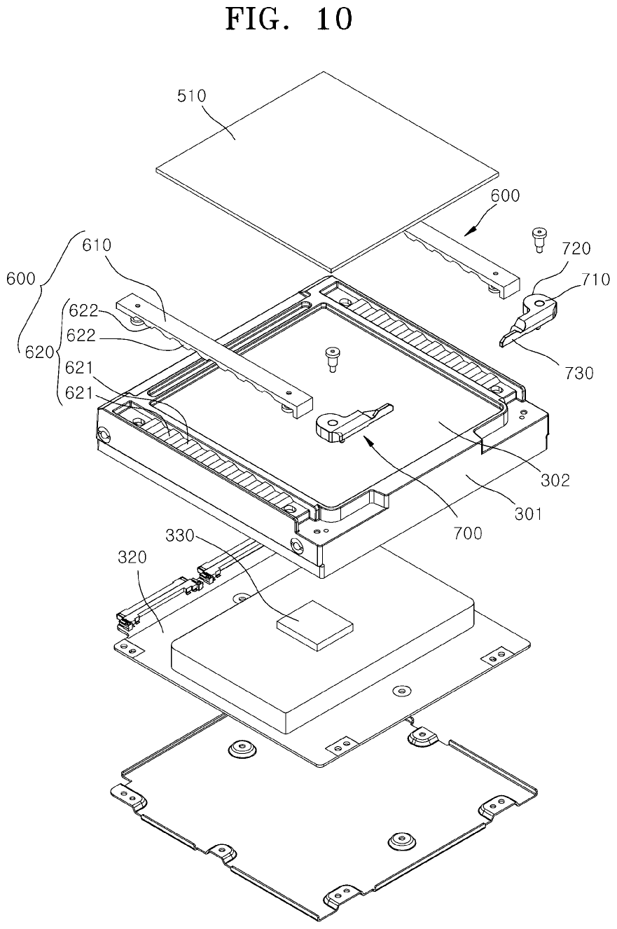

FIG. 8 is a perspective view schematically illustrating the configuration of an electronic module according to an embodiment of the present disclosure, FIG. 9 is a cross-sectional perspective view schematically illustrating the configuration of the electronic module according to the embodiment of the present disclosure, and FIG. 10 is an exploded perspective view schematically illustrating the configuration of the electronic module according to the embodiment of the present disclosure.

Referring to FIGS. 1 through 10, the electronic module 300 may include a module casing 310, a board 320, a heating element 330, and a contact 340.

The module casing 310 may form a schematic outline of the electronic module 300 and may support the board 320, the heating element 330, and the contact 340 as a whole. The module casing 310 may be formed to have the shape of a cuboidal box having a first side 301 and a second side 302. The first side 301 and second side 302 of the module casing 310 may be the same sides as the first side 301 and second side 302 of the electronic module 300 described above. The module casing 310 may be formed to be hollow. The module casing 310 may be formed of a metal material, such as aluminum, steel, or the like, that has sufficient rigidity and high thermal conductivity.

The board 320 may be disposed inside the module casing 310. The board 320 may be a conventional printed circuit board having the shape of a roughly flat plate. The board 320 may be secured to a bottom surface of the module casing 310.

The heating element 330 may be mounted on the board 320. Examples of the heating element 330 may include various types of electronic elements, such as CPUs, microprocessors, IC chips, diodes, and the like, that may be mounted on the board 320 to implement functionality of the electronic module 300. The heating element 330 may be heated by its own resistor or the like in the course of performing the functions of the electronic module 300.

The contact 340 may extend from the module casing 310 and may be in contact with the heating element 330. That is, the contact 340 may function as a configuration to transfer heat generated by the heating element 330 to the module casing 310. The contact 340 may extend from an inner surface of the module casing 310 toward the heating element 330. A first side of the contact 340 may be in direct contact with an outer surface of the heating element 330. The contact 340 may be formed of a material having a high thermal conductivity. In an example, the contact 340 may be formed of the same material as the module casing 310.

On one side of the electronic module 300, a control module C may be disposed so as to be electrically connected to the plurality of electronic modules 300 to control the operations of the electronic modules 300. The control module C may include an electronic control unit (ECU), a central processing unit (CPU), a processor, or a system on chip (SoC) that may drive an operating system or application to control the operations of the electronic modules 300 and may perform various data processing and operations. The control module C may be formed to have a roughly cuboidal box shape. The control module C may be disposed with an inner side facing the second end 202 of the slot 200. The control module C may be electrically connected to the plurality of electronic modules 300 via connectors (not shown) protruding from the electronic modules 300. The control module C may be secured to the housing 100 by various types of fastening means, including bolting, welding, interference-fitting, or the like.

The cooling member 400 may be disposed outside the slot 200 and may function as a configuration for cooling the electronic module 300. Accordingly, the cooling member 400 may prevent the functionality of the electronic module 300 from being degraded by self-heating of the electronic module 300 during operation of the electronic module 300.

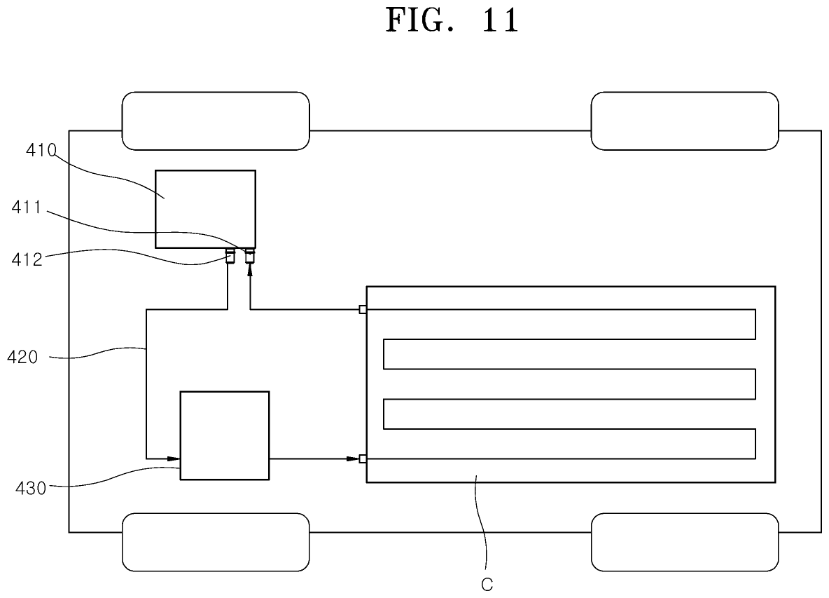

FIG. 11 is a view schematically illustrating the configuration of a cooling element according to an embodiment of the present disclosure.

Referring to FIGS. 1, 2, and 11, the cooling member 400 may include a heat sink 410, a circulation line 420, and a chiller 430.

The heat sink 410 may be disposed facing the first end 201 of the slot 200. The heat sink 410 may be formed to have a roughly cuboidal box shape. An inner surface of the heat sink 410 disposed facing the first end 201 of the slot 200 may be in contact with the first surface 301 of the electronic module 300. An area of the inner surface of the heat sink 410 may be larger than the sum of the areas of the first surfaces 301 of the plurality of electronic modules 300. Accordingly, the inner surface of the heat sink 410 may be in contact with the first surfaces 301 of the plurality of electronic modules 300 simultaneously.

A coolant may flow into or out of the heat sink 410. More specifically, the heat sink 410 may be provided with an inlet port 411 allowing a coolant to flow into the interior of the heat sink 410 and an outlet port 412 allowing the coolant to flow out of the interior of the heat sink 410. The heat sink 410 may be internally provided with a cooling flow path (not shown) that is connected at both ends to the inlet port 411 and outlet port 412, respectively to guide a flow of coolant. The heat sink 410 may absorb heat generated by the electronic modules 300 by heat exchange between the coolant flowing through the cooling flow path and the electronic modules 300, thereby cooling the electronic modules 300. The heat sink 410 may be formed of a metal material with high thermal conductivity, such as aluminum, to further improve the heat exchange efficiency between the coolant flowing therein and the electronic modules 300.

An inner surface of the heat sink 410 may be in contact with an end surface of the first plate 110. Accordingly, the heat sink 410 may absorb heat transferred from the electronic modules 300 to the housing 100, thereby improving the cooling efficiency of the electronic modules 300 and preventing heat generated by any one of the electronic modules 300 from being transferred to other electronic modules 300.

The circulation line 420 may be connected to the heat sink 410, and coolant may be circulated therethrough. That is, the circulation line 420 may function as a configuration to guide a flow of coolant into and out of the heat sink 410. The circulation line 420 may be formed to have the shape of a tube that is hollow and open at both ends. The two ends of the circulation line 420 may be connected to the inlet port 411 and the outlet port 412 of the heat sink 410, respectively. A pump (not shown) may be connected to the circulation line 420 to allow the coolant in the circulation line 420 to flow in a direction from the outlet port 412 toward the inlet port 411.

The chiller 430 may be connected to the circulation line 420 to cool the coolant flowing through the circulation line 420. In other words, the chiller 430 may function as a configuration to reduce the temperature of the coolant heated during passage through the heat sink 410 to maintain the cooling capabilities of the heat sink 410. Examples of the chiller 430 may include various types of heat exchangers in which both ends are connected to the circulation line 420 so that the coolant flowing through the circulation line 420 heat-exchanges with a separate refrigerant or air to cool the coolant entering the heat sink 410.

The circulation line 420 may be connected to a battery heat sink B cooling a vehicle's battery. That is, the circulation line 420 may continuously connect a coolant path for cooling the vehicle's battery with a coolant path for cooling the electronic modules 300. Accordingly, the cooling member 400 may cool the electronic modules 300 using the coolant circulating through a battery cooling system pre-installed in a vehicle, thereby reducing installation costs.

The heat transfer member 500 may be connected to the electronic module 300 to transfer heat generated by the electronic module 300 to the cooling member 400. In other words, the heat transfer member 500 may function as a configuration to direct the heat generated by the electronic modules 300 toward the cooling member 400. Accordingly, the heat transfer member 500 may further improve the cooling efficiency of the electronic modules 300 by quickly transferring the heat generated by the electronic modules 300 toward the cooling member 400.

The heat transfer member 500 may include a heat pipe 510.

Examples of the heat pipe 510 may include various types of heat transfer means that may absorb heat from an external heat source to cause the working fluid to evaporate to a gaseous state, may move the working fluid from an evaporating section to a condensing section by an expansion force occurring during the evaporating process, and may transfer the heat generated by the external heat source in one direction.

A plurality of heat pipes 510 may be provided. Respective heat pipes 510 may be individually mounted on different electronic modules 300.

The heat pipe 510 may be formed to have the shape of a roughly flat plate, an undersurface of which may rest on the second side 302 of the electronic module 300. The heat pipe 510 may transfer heat, which was transferred from the heating element 330 to the module casing 310, in a direction toward the first surface 301 in contact with the heat sink 410. The top surface of the heat pipe 510 may be spaced apart from the housing 100, more specifically, the undersurface of the first plate 110 surrounding the top surface of the slot 200. Accordingly, the heat pipe 510 may prevent heat transferred from any one electronic module 300 from being transferred through the housing 100 to a neighboring electronic module 300.

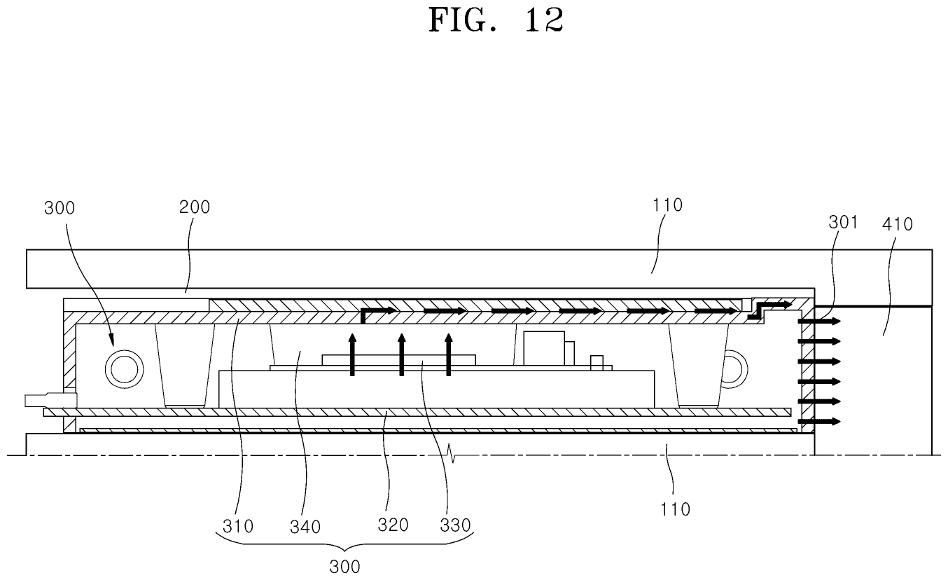

FIG. 12 is a diagram illustrating a heat dissipation process by a cooling member and a heat transfer member according to an embodiment of the present disclosure.

Referring to FIG. 12, heat generated by the heating element 330 may be transferred to the second side 302 of the module casing 310 via the contact 340.

The heat transferred to the second side 302 of the module casing 310 is transferred to the heat pipe 510, and the heat pipe 510 diverts the heat transfer direction toward the first side 301.

The heat transferred to the first surface 301 is dissipated from the module casing 310 by heat exchange with the coolant passing through the heat sink 410 in contact with the first surface 301.

The electronic device according to this embodiment may further include a fastening member 600 and an adjustment member 700.

The fastening member 600 may be movably mounted on the electronic module 300. Depending on the movement direction of the fastening member 600, the electronic module 300 may be selectively fastened to the housing 100. Accordingly, the fastening member 600 may facilitate attachment/detachment of the electronic module 300 to/from the interior of the slot 200 when assembly or replacement of the electronic module 300 is required, and may prevent the electronic module 300 from being detached from the slot 200 when the electronic module 300 is fully inserted into the slot 200.

A plurality of fastening members 600 may be provided. The plurality of fastening members 600 may be respectively mounted on electronic modules 300.

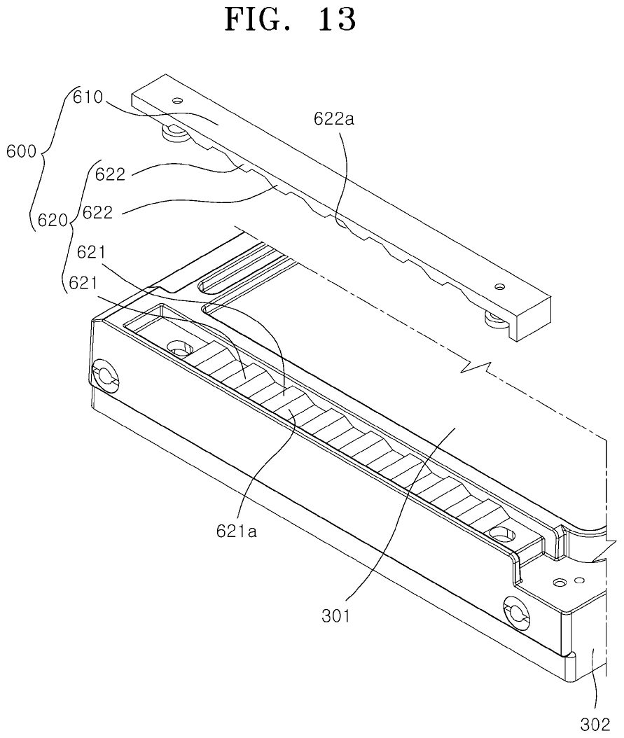

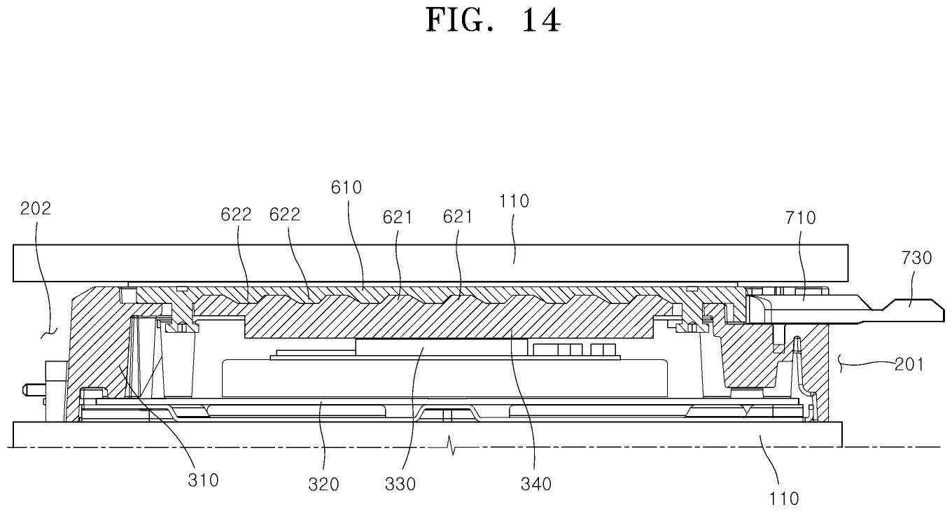

FIG. 13 is a perspective view schematically illustrating the configuration of a fastening member according to an embodiment of the present disclosure, and FIG. 14 is a cross-sectional view schematically illustrating the configuration of the fastening member according to the embodiment of the present disclosure.

Referring to FIGS. 13 and 14, the fastening member 600 may include a base member 610 and a switching member 620.

The base member 610 may be disposed facing the electronic module 300 and may be reciprocally movable along a first direction. Here, the first direction may refer to a direction parallel to the insertion direction of the electronic module 300 into the slot 200. In an example, the first direction may refer to a direction parallel to the longitudinal direction of the housing 100 and facing a direction from the first end 201 toward the second end 202 of the slot 200. The base member 610 may be formed to have a roughly rod-like shape. The base member 610 may be disposed so that a longitudinal direction thereof is parallel to the longitudinal direction of the housing 100. An undersurface of the base member 610 may be disposed to face the second side 302 of the electronic module 300, i.e., the top surface the module casing 310. The base member 610 may be slidably supported on the second side 302 via the switching member 620 described below. A top surface of the base member 610 may be disposed to face the undersurface of the first plate 110 surrounding the top surface of the slot 200. The top surface of the base member 610 may be spaced apart a predetermined distance from the undersurface of the first plate 110 in an initial position.

A plurality of stationary bodies 610 may be provided. In an example, the stationary bodies 610 may be provided in a pair and be spaced apart from each other along the width direction of the housing 100 on the second side 302 of the electronic module 300.

The switching member 620 may be provided between the base member 610 and the electronic module 300. The switching member 620 may switch the movement direction of the base member 610 from the first direction to the second direction when the base member 610 is moved in the first direction. Here, the second direction may refer to a direction intersecting the first direction. In an example, the second direction may refer to an upwardly inclined direction extending from the first end 201 toward the second end 202 of the slot 200. Accordingly, when the base member 610 is moved in the first direction, as the movement direction is switched to the second direction by the switching member 620, the top surface may contact the housing 100, more specifically the underside of the first plate 110, thereby securing the electronic module 300 to the interior of the slot 200.

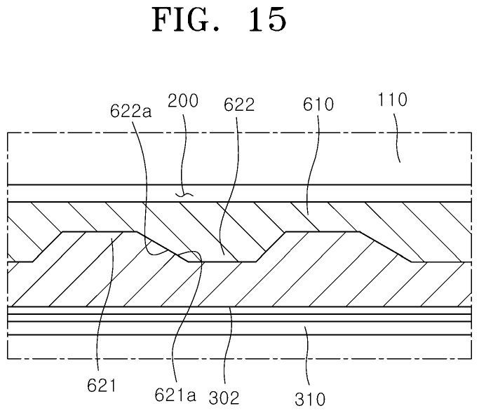

FIG. 15 is an enlarged view schematically illustrating the configuration of a switching member according to an embodiment of the present disclosure.

Referring to FIGS. 13 through 15, the switching member 620 may include a first wedge 621 and a second wedge 622.

The first wedge 621 may protrude from the second side 302 of the electronic module 300 toward the base member 610. A first side of the first wedge 621 may have a first inclined surface 621a disposed at an inclination with respect to the first direction. In an example, the first inclined surface 621a may be formed on a side of the overall perimeter of the first wedge 621 that is disposed to face the first end 201 of the slot 200. The inclination angle of the first inclined surface 621a may be the same as the inclination angle of the second direction relative to the first direction. Accordingly, the first wedge 621 may be formed to have an approximately trapezoidal cross-sectional shape. A plurality of first wedges 621 may be provided. The plurality of first wedges 621 may be arranged along the longitudinal direction of the base member 610.

The second wedge 622 may protrude from the base member 610 toward the first wedge 621 and may movably support the base member 610 relative to the first wedge 621. A first side of the second wedge 622 may have a second inclined surface 622a disposed at an inclination with respect to the first direction and in contact with the first inclined surface 621a. In an example, the second inclined surface 622a may be formed on a side of the overall perimeter of the second wedge 622 that is disposed to face the second end 202 of the slot 200. The inclination angle of the second inclined surface 622a may be the same as the inclination angle of the second inclined surface 621a. Accordingly, the second inclined surface 622a may be in contact with the first inclined surface 621a.

As illustrated in FIG. 15, the second wedge 622 may remain in contact with the second surface 302 at its end when the base member 610 is in its initial position. When the base member 610 is moved in the first direction, the second wedge 622 may switch the movement direction of the base member 610 from the first direction to the second direction while the second inclined surface 622a is moved in the second direction along the first inclined surface 621a.

The lengths of the first inclined surface 611a and the second inclined surface 622a along the second direction may be greater than the travel distance of the base member 610 in the second direction. Accordingly, the first inclined surface 611a and the second inclined surface 622a may remain in contact at all times during the movement of the base member 610.

A plurality of second wedges 622 may be provided. The plurality of second wedges 622 may be arranged along the longitudinal direction of the base member 610. The plurality of second wedges 622 may be arranged alternately with the first wedges 621. That is, any one second wedge 622 may be arranged between neighboring pair of first wedges 611.

The base member 610, the first wedges 621, and the second wedges 622 may be formed of a metal material with high thermal conductivity, such as aluminum. Accordingly, the base member 610, first wedges 621, and second wedges 622 may dissipate a portion of the heat transferred to the heat pipe 510 into the housing 100 to further improve the heat dissipation efficiency of the electronic modules 300.

The adjustment member 700 may be connected to the electronic module 300 to regulate the movement of the base member 610. That is, the adjustment member 700 may function as a configuration to generate and release a driving force to move the base member 610 in the first direction. A plurality of adjustment members 700 may be provided. The plurality of adjustment members 700 may be respectively mounted on the fastening members 600.

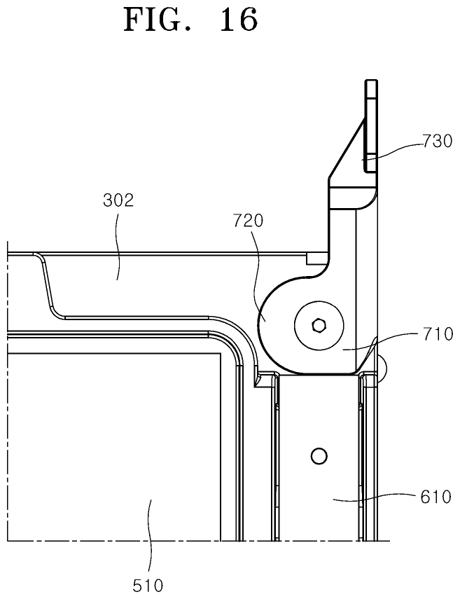

FIG. 16 is a view schematically illustrating the configuration of an adjustment member according to an embodiment of the present disclosure.

Referring to FIGS. 10 and 16, the adjustment member 700 may include an adjustment body 710, a cam 720, and a lever 730.

The adjustment body 710 may be rotatably connected to the electronic module 300 and may support the cam 720 and lever 730 as a whole, as described below. The adjustment body 710 may be disposed on the second side 302 of the electronic module 300. The adjustment body 710 may be disposed to face a first end of the base member 610 that is disposed to face the first end 201 in the interior of the slot 200. The adjustment body 710 may be in direct contact with the first end of the base member 610 when the base member 610 is in its initial position, or may be spaced apart a predetermined distance from the first end of the base member 610. The adjustment body 710 may be rotatably supported on the second surface 302 of the electronic module 300, such as by pins, in clockwise and counterclockwise directions about a rotation axis. The rotation axis of the adjustment body 710 may be arranged parallel to the height direction, i.e. the vertical direction of the housing 100. The specific shape of the adjustment body 710 is not limited to the shape illustrated in FIG. 16, but may be varied in design within the technical scope of the shape rotatable about a rotation axis on the second surface 302.

The cam 720 may be disposed on one side of the adjustment body 710 to press or release the base member 610 in the first direction depending on the rotation direction of the adjustment body 710. The cam 720 may protrude from an outer surface of the adjustment body 710 in a radial direction of the adjustment body 710. The protrusion length of the cam 720 may be greater than the gap between the adjustment body 710 and the base member 610. The cam 720 may contact the first end of the base member 610 as the adjustment body 710 is rotated from its initial position in one direction (counterclockwise with respect to FIG. 16). In this case, the adjustment body 710 may press the base member 610 in the first direction and move the base member 610 in the first direction as the adjustment body 710 protrudes in the radial direction of the adjustment body 710. The cam 720 may then disengage from the first end of the base member 610 as the adjustment body 710 is rotated in opposite direction and returned to its initial position, releasing the pressurizing force on the base member 610. The initial position of the adjustment body 710 may be varied in design to a position where the cam 720 is not in contact with the base member 610.

The lever 730 may function as a configuration for transmitting an external force applied from a user to the adjustment body 710. The lever 730 may protrude radially from the other side of the adjustment body 710, i.e., the side of the entire outer surface of the adjustment body 710 where the cam 720 is not formed. The lever 730 may be formed in the form of various types of handles that are grippable by a user. The lever 730 may be arranged parallel to the longitudinal direction of the housing 100 when the adjustment body 710 is in its initial position, and may protrude outwardly from the housing 100.

The operations of the fastening member 600 and the adjustment member 700 according to an embodiment of the present disclosure will now be described.

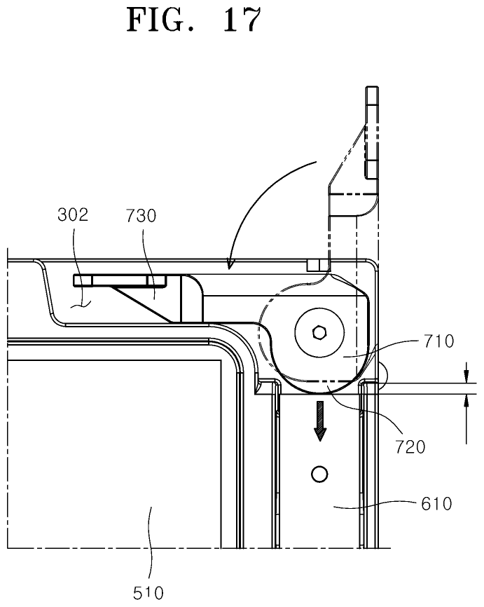

FIGS. 17 through 19 are views schematically illustrating an operation process of the fastening member and the adjustment member according to an embodiment of the present disclosure.

Referring to FIG. 17, with the electronic module 300 fully inserted into the interior of the slot 200, as the user rotates the lever 730 in a counterclockwise direction (relative to FIG. 17), the adjustment body 710 is rotated counterclockwise from its initial position together with the lever 730.

The cam 720 is rotated counterclockwise together with the adjustment body 710 and contacts the first end of the base member 610.

As the cam 720 protrudes radially from the adjustment body 710, the cam 720 presses the base member 610 in the first direction, and the base member 610 is moved along the first direction.

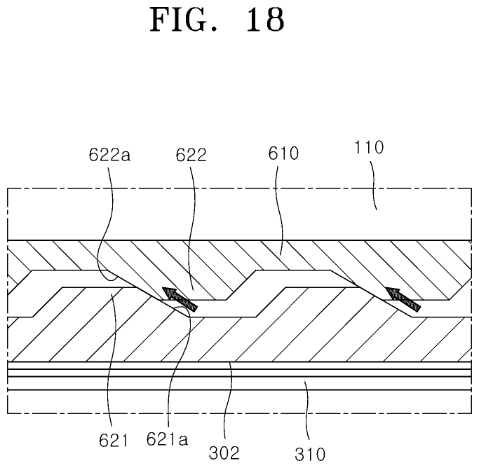

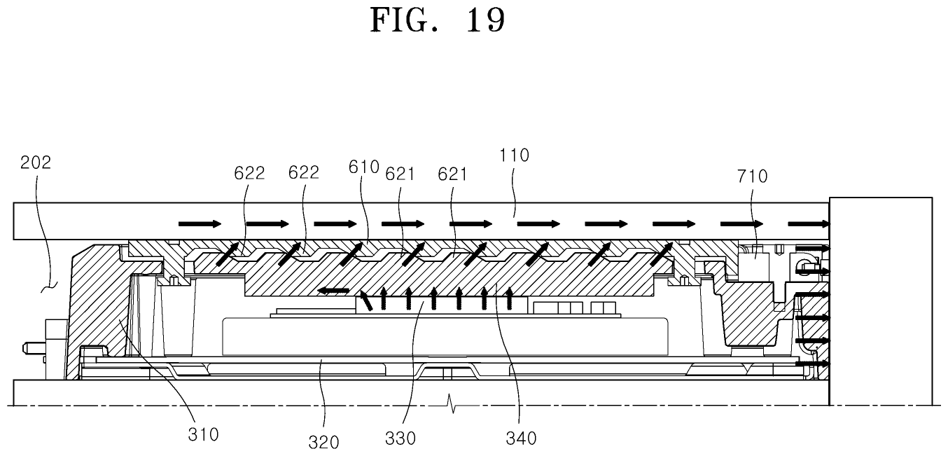

Referring to FIGS. 18 and 19, as the base member 610 is moved along the first direction, the second inclined surface 622a is moved along the first inclined surface 621a in the second direction, switching the movement direction of the base member 610 to the second direction.

As the base member 610 is moved in the second direction, the top surface contacts the undersurface of the first plate 110.

As the base member 610 contacts the first plate 110, the electronic module 300 may be fixed in the interior of the slot 200 by a frictional force acting between the base member 610 and the first plate 110.

On the other hand, as the base member 610, the first wedge 621, and the second wedge 622 remain in contact at all times, a portion of the heat transferred from the heating element 330 to the module casing 310 may be transferred to the first plate 110 via the first wedge 621, the second wedge 622, and the base member 610 in sequence.

In this case, as the heat sink 410 contacts the end face of the first plate 110, the heat transferred to the first plate 110 may be heat-exchanged with the coolant flowing through the interior of the heat sink 410 and may be dissipated from the first plate 110.

While the present disclosure has been described with reference to the embodiments depicted in the drawings, the embodiments are for illustrative purposes only, and those skilled in the art to which the present technology pertains will understand that various modifications of the embodiments and any other embodiments equivalent thereto are available. Therefore, the scope of technical protection of the present disclosure is to be defined by the appended claims.

What is claimed is:

1. An electronic device comprising:
a housing;
a slot disposed in an interior of the housing, the slot configured to hold an electronic module;
a cooling member disposed outside the slot and configured to cool the electronic module when the electronic module is inserted in the slot; and
a heat transfer member configured to be connected to the electronic module when the electronic module has been inserted in the slot for transfer of heat from the electronic module to the cooling member.

2. The electronic device of claim 1, wherein the plurality of slots adjoin each other in the interior of the housing.

3. The electronic device of claim 1, wherein the slot comprises a first end and a second end spaced apart from each other, and the cooling member comprises:
a heat sink facing the first end of the slot and configured to be in contact with the electronic module inserted in the slot and configured to permit a coolant to be introduced or discharged through the heat sink;
a circulation line connected to the heat sink and configured to permit the coolant to be circulated through the circulation line; and
a chiller connected to the circulation line and configured to cool the coolant flowing through the circulation line.

4. The electronic device of claim 1, wherein the electronic module comprises:
a first side disposed facing the first end of the slot; and
a second side intersecting the first side of the electronic module, wherein the heat transfer member includes a heat pipe on the second side of the electronic module.

5. The electronic device of claim 4, wherein a cross-sectional area of the electronic module is smaller than a cross-sectional area of the slot, and the heat pipe is spaced apart from the housing.

6. The electronic device of claim 1, further comprising: a fastening member movably mounted on the electronic module and configured to selectively fasten the electronic module to the housing depending on a movement direction of the fastening member.

7. The electronic device of claim 6, wherein the cross-sectional area of the electronic module is smaller than the cross-sectional area of the slot, and the fastening member comprises:
a base member reciprocally mounted along a first direction parallel to an insertion direction of the electronic module into the slot; and
a switching member disposed between the base member and the electronic module and configured to switch the movement direction of the base member from the first direction to a second direction intersecting the first direction, the base member being in contact with the housing as the base member moves in the second direction.

8. The electronic device of claim 7, wherein the switching member comprises:
a first wedge having a first inclined surface protruding from the electronic module and disposed in a position that is inclined relative to the first direction; and
a second wedge having a second inclined surface protruding from the base member and being in contact with the first inclined surface.

9. The electronic device of claim 8, wherein the first wedge has a trapezoidal cross-sectional shape.

10. The electronic device of claim 8, including a plurality of first wedges and a plurality of the second wedges, and the plurality of the first wedges and the plurality of the second wedges are arranged alternately along the longitudinal direction of the base member.

11. The electronic device of claim 8, wherein a length of the first inclined surface and a length of the second inclined surface along the second direction are greater than a travel distance of the stationary body in the second direction.

12. The electronic device of claim 7, further comprising an adjustment member configured to be connected to the electronic module to regulate movement of the base member.

13. The electronic device of claim 12, wherein the adjustment member comprises:
an adjustment body configured to be rotatably connected to the electronic module;
a cam disposed on one side of the adjustment body and configured to press or release the base member in the first direction depending on a rotation direction of the adjustment body; and
a lever extending from another side of the adjustment body.

14. The electronic device of claim 13, wherein the cam is disposed to protrude radially from an outer surface of the adjustment body.

15. The electronic device of claim 14, wherein a protrusion length of the cam is greater than a gap between the adjustment body and the base member.
